(19) United States
(12) Patent Application Publication
(10) Pub. No.: US 2026/0169105 A1
(43) Pub. Date: Jun. 18, 2026

(54) ANALYTICAL ULTRACENTRIFUGATION WITH NMR DETECTION (AUC-NMR)

(71) Applicant: Oregon State University, Corvallis, OR (US)

(72) Inventor: Thomas Osborn Popp, Corvallis, OR (US)

(73) Assignee: Oregon State University, Corvallis, OR (US)

(21) Appl. No.: 19/424,468

(22) Filed: Dec. 18, 2025

Related U.S. Application Data
(60) Provisional application No. 63/735,720, filed on Dec. 18, 2024.

(51) Int. Cl. G01R 33/30; G01N 24/08

(52) U.S. Cl. CPC G01R 33/307; G01N 24/08

(57) ABSTRACT

A method for performing analytical ultracentrifugation with nuclear magnetic resonance detection, the method including: applying a first magnetic field having a first field direction to a spinner, the spinner containing an analyte, and the spinner being disposed in a cavity region of a stator housing; physically rotating the spinner at a spin angle with respect to the first field direction, thereby inducing sedimentation of the analyte; applying a second magnetic field with a second field direction across the analyte; and acquiring a spatially-resolved NMR signal, thereby characterizing the analyte by a radial position of the analyte in the spinner. An NMR probe including a stator housing having a cavity region; a spinner; a radiofrequency coil; a field generator; a spinner drive apparatus for providing, at a coupling point thereof, a drive force; and coupling apparatus for coupling the drive force to the spinner.

### CROSS-REFERENCE TO RELATED APPLICATION

This application claims priority to Provisional Application No. 63/735720 filed Dec. 18, 2024, the entire disclosure of which is hereby incorporated by reference.

### BACKGROUND

Nuclear Magnetic Resonance (NMR) spectroscopy is a powerful and non-destructive analytical technique commonly utilized in the study of proteins and other biomolecules. To perform NMR, a radiofrequency (RF) spectrum of a sample placed in a strong magnetic field is collected, and peaks within that spectrum provide information about the structure and dynamics of molecules within the sample.

The NMR spectra of solution-state samples are typically characterized by highly resolved, sharp peaks (the isotropic chemical shift) that facilitate subsequent analysis. However, in diamagnetic materials, the energy levels of a nuclear spin are perturbed by the local chemical environment through multiple interactions. For instance, J-coupling is a magnetic coupling between spins that is mediated through chemical bonds. As another example, chemical shielding depends on the distribution of electron density around the nucleus and gives rise to “chemical shift”. Dipolar coupling is a magnetic coupling between spins that acts through space.

Because of these effects, the frequencies measured in an NMR spectrum can be highly sensitive to the local chemical surroundings about the nucleus. The magnitude of this perturbance to the nuclear spin energies depends on the orientation of the chemical environment with respect to the magnetic field. In solution state NMR, molecules tumble rapidly, and thus average out the contributions from these effects, leaving a spectrum with only the isotropic chemical shift and j-couplings.

In the solid state however, these interactions result in broad peaks that can make our attempts to study solids with NMR more difficult. Thus, for samples with slower molecular motions, such as solids, gels, and large macromolecular complexes, anisotropic nuclear spin interactions such as dipolar coupling cause significant spectral broadening, and a technique known as magic-angle spinning (MAS) must be employed to obtain high-resolution spectra.

To perform MAS, specialized instrumentation is required to pneumatically spin the sample rapidly about an axis inclined at 54.74° (the “magic angle”) with respect to the magnetic field during the NMR experiment.

Analytical ultracentrifugation (AUC) is a technique designed to provide information about the size and shape of molecules. In AUC, a solution of a macromolecule is placed into a special rotor and centrifuge. When the centrifuge is operated, optical detection (i.e., absorbance, interference, fluorescence optics) is performed to detect a concentration gradient.

The measurement of the concentration gradient profile may be performed at equilibrium (sedimentation equilibrium, or SE), or over time (sedimentation velocity, or SV). Either SE or SV may be used to obtain sedimentation coefficients.

Optical detection methods limit what samples can be studied by AUC to highly purified solutions containing one or maybe two molecules, as many macromolecules have similar optical properties.

The present disclosure addresses these and other long-felt and unmet needs in the art.

### SUMMARY

This summary is provided to introduce a selection of concepts in a simplified form that are further described below in the Detailed Description. This summary is not intended to identify key features of the claimed subject matter, nor is it intended to be used as an aid in determining the scope of the claimed subject matter.

In an aspect, the present disclosure provides methods for performing analytical ultracentrifugation with nuclear magnetic resonance (AUC-NMR) detection, the methods including: applying a first magnetic field having a first field direction to a spinner, said spinner comprising an analyte, and said spinner being disposed in a cavity region of a stator housing; physically rotating the spinner at a spin angle with respect to the first field direction, thereby inducing sedimentation of the analyte; applying a second magnetic field with a second field direction across the analyte, thereby generating a magnetic field gradient; and acquiring a spatially-resolved NMR signal, thereby characterizing the analyte by a radial position of the analyte in the spinner.

In some embodiments, the spin angle is about 54.74°.

In some embodiments, the magnetic field gradient is linear.

In some embodiments, the magnetic field gradient is non-linear.

In some embodiments, the methods further include processing the spatially-resolved NMR signal to generate a radially-resolved NMR spectrum.

In some embodiments, the methods further include processing the radially-resolved NMR spectrum to generate a radial concentration distribution of the analyte.

In some embodiments, the methods further include processing the radial concentration distribution to generate sedimentation coefficients of the analyte.

In some embodiments, the methods further include performing sedimentation equilibrium analytical ultracentrifugation on the radial concentration distribution.

In some embodiments, the methods further include performing sedimentation velocity analytical ultracentrifugation on the radial concentration distribution.

In some embodiments, the spatially-resolved NMR signal is based on slice-selective excitation methods.

In some embodiments, the spatially-resolved NMR signal is based on phase-encoded imaging methods.

In some embodiments, the second magnetic field is generated by pulsing a direct current through a field generator running substantially parallel to the rotational axis of the spinner.

In some embodiments, the direct current is pulsed from about 0.01 A to about 50 A.

In some embodiments, a rate of rotation of the spinner is sufficient so that the sedimentation of the analyte establishes an analyte concentration gradient with respect to the rotational axis of the spinner.

In some embodiments, the rate of rotation is from about 1 Hz to about 100,000 Hz.

In some embodiments, the acquiring the spatially-resolved NMR signal is performed by applying, from a radiofrequency coil, a sequence of radiofrequency pulses to the spinner.

In some embodiments, a nucleus providing the NMR signal is selected from the group consisting of a ¹H NMR signal, a ¹³C NMR signal, a ³¹P NMR signal, and a ¹⁹F NMR signal.

In some embodiments, the analyte is selected from the group consisting of proteins, liposomes, nanoparticles, colloids, polymers, biopolymers, small molecules, or combinations thereof.

In some embodiments, a strength of the first magnetic field is from about 0.1 tesla to about 100 tesla.

In some embodiments, the second magnetic field varies in magnitude and direction over time.

In an aspect, the present disclosure relates to an NMR probe for performing analytical ultracentrifugation (AUC) with nuclear magnetic resonance (NMR) detection, the NMR probe including: a stator housing having a cavity region; a spinner disposed in the cavity region, wherein the spinner is configured to contain an analyte; a radiofrequency coil disposed in the stator housing and configured to substantially surround the spinner; a field generator disposed in the stator housing, said field generator being configured to apply a magnetic field to the spinner; a spinner drive apparatus for providing, at a coupling point thereof, a drive force having an amplitude configured to vary as a function of time with a rotation frequency; and coupling apparatus for coupling the drive force from the coupling point of said spinner drive apparatus to said spinner, thereby rotating the spinner at the rotation frequency.

In some embodiments, the field generator is a gradient wire placed to one side of the spinner, wherein the gradient wire is configured to receive direct current pulses.

In some embodiments, the gradient wire has a diameter from about 0.01 mm to about 2 mm.

In some embodiments, the gradient wire is positioned from about 0.01 mm to about 2 mm away from the spinner.

In some embodiments, the radiofrequency coil is configured to provide a radiofrequency pulse of from about 10 MHz to about 1500 MHz.

In an aspect, the present disclosure relates to a method for performing MRI imaging using any of the NMR probes described herein.

In an aspect, the present disclosure relates to a method for performing diffusion NMR using any of the NMR probes described herein.

In an aspect, the present disclosure relates to a method for performing coherence selection using any of the NMR probes described herein.

### DESCRIPTION OF THE DRAWINGS

The foregoing aspects and many of the attendant advantages of this invention will become more readily appreciated as the same become better understood by reference to the following detailed description, when taken in conjunction with the accompanying drawings.

FIG. 1A depicts a schematic illustration of an NMR probe, according to embodiments of the present disclosure.

FIG. 1B depicts a schematic illustration of a spinner according to FIG. 1A.

FIG. 2A depicts a perspective view of an NMR probe for performing AUC-NMR, according to embodiments of the present disclosure.

FIG. 2B depicts a side view of the NMR probe according to FIG. 2A.

FIG. 2C depicts a cross-sectional schematic view of an analyte sample space for depicting a concentration gradient relative to a field generator, according to embodiments of the present disclosure.

FIG. 3A depicts a spatial distribution of the z-component of the magnetic field (Bz) produced by the current in the field generator of the NMR probe of FIG. 2A. Contours follow lines of equal Bz, represented visually by the length of each arrow.

FIG. 3B depicts variation in Bz as a function of azimuthal angle at two fixed radius values for the NMR probe of FIG. 2A.

FIG. 3C depicts a radial concentration profile obtained by NMR detection for three different detected species (dot dashed, solid, and dashed lines), and corresponding NMR spectra (black line on white hatching, solid fill, white line on black hatching) for 3 radial slices for the NMR probe of FIG. 2A. The solid filled feature represents the presence of a dimer species of the molecule represented by the solid line.

FIG. 3D depicts a gradient correction applied to NMR signal determined at radius positions A-E, demonstrating correction for signal broadening.

FIG. 3E depicts isopycnic separation of signals at three radial slices, depicting (1) a radial slice containing no analyte, (2) a radial slice containing a first analyte with a first NMR signal, and (3) a radial slice containing a second analyte with a second NMR signal.

### DETAILED DESCRIPTION

The present disclosure relates to methods and devices that expand the reach of magic-angle spinning NMR spectroscopy (“MAS NMR”) into methods of performing analytical ultracentrifugation (AUC) with NMR-based detection (AUC-NMR). AUC has long been considered the “gold standard” for characterizing the size and shape of biological macromolecules in solution in a non-destructive manner. Devices of the present disclosure allow AUC to benefit from the spectral resolution afforded by NMR detection as a powerful tool for the characterization of complex biochemical systems.

Analytical ultracentrifugation (AUC) is a powerful and versatile technique that can provide detailed information about the size, shape, mass, and binding properties of biological macromolecules in the solution state based on how they sediment under centrifugation. In the typical operation of AUC, the distribution of particles in solution during centrifugation is monitored using an optical detection method such as absorbance, interference, or fluorescence optics. In the present disclosure, a novel AUC methodology is described that uses NMR for detection and an MAS rotor as the centrifuge.

An MAS rotor (also referred to herein as a “spinner”) is a particularly potent ultracentrifuge. At typical sizes and spinning speeds, MAS rotors may readily apply centrifugal forces of well over a million times Earth's gravity at the inner wall of the rotor, making them capable of sedimenting proteins and other biomolecules from solution.

In an aspect, the present disclosure relates to an NMR probe for performing AUC-NMR, the NMR probe including: a stator housing having a cavity region; a spinner disposed in the cavity region, wherein the spinner is configured to contain an analyte; a radiofrequency coil disposed in the stator housing and configured to substantially surround the spinner; a field generator disposed in the stator housing, said field generator being configured to apply a magnetic field to the spinner; a spinner drive apparatus for providing, at a coupling point thereof, a drive force having an amplitude configured to vary as a function of time with a rotation frequency; and coupling apparatus for coupling the drive force from the coupling point of said spinner drive apparatus to said spinner, thereby rotating the spinner at the rotation frequency.

Additionally, while reference is made throughout to the use of the NMR probe in the context of performing AUC-NMR for clarity and brevity, it is to be understood that the NMR probe is not limited to use in performing AUC-NMR, and can be used for any experimental technique involving a magnetic field gradient, including MRI imaging, diffusion NMR, coherence selection, and other related techniques, and that such techniques are within the scope of the present disclosure.

An NMR probehead (also referred to as an NMR “probe”) is the interface between an analyte sample and an NMR spectrometer. Sample spinners for MAS experiments are integrated into an NMR probe to be used in NMR experiments.

As used herein, “analyte” refers to a chemical composition suitable for analysis via NMR experimentation. In this regard, the analyte may refer to a single chemical composition, and/or to two or more chemical compositions. Such combinations of one or more chemical compositions may be present in any suitable form, including as a single composition in a pure form, a single composition in an analyte solution, two or more chemical compositions mixed in their pure form, or two or more chemical compositions in an analyte solution. In some embodiments, the analyte comprises one or more chemical compositions in an analyte solution comprising a solvent suitable for NMR spectroscopy, such as a deuterated solvent.

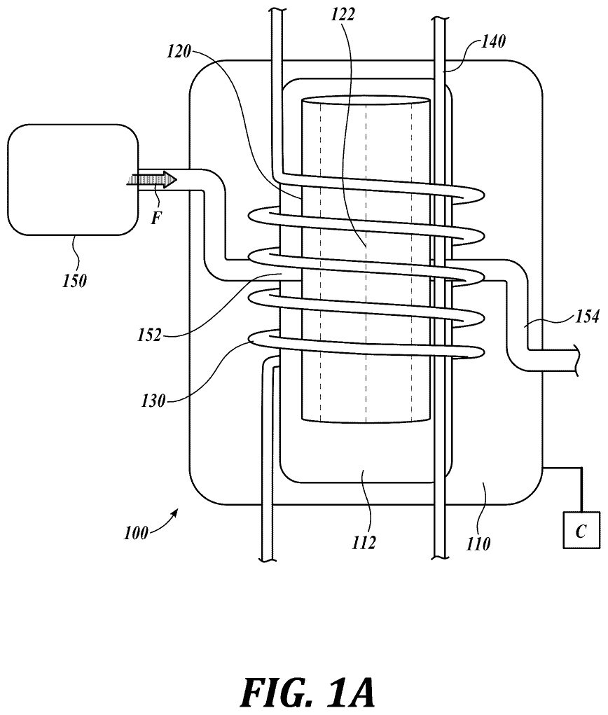

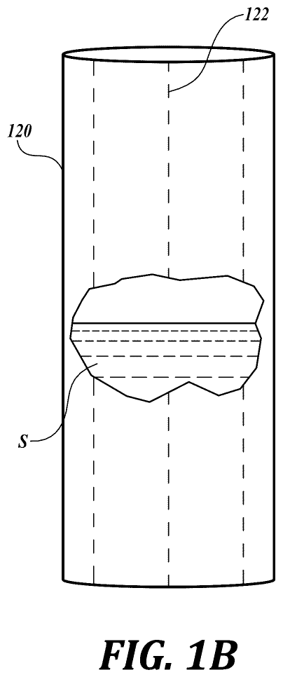

In this regard, FIG. 1A-FIG. 1B depict examples of sample spinners in an NMR probe according to the present disclosure, where the spinning rate is monitored as a function of gas pressure and flow rate.

FIG. 1A illustrates a schematic of NMR probe 100 according to embodiments of the present disclosure. NMR probe 100 is depicted to include stator housing 110, cavity region 112, spinner 120 with coupling apparatus 122, radiofrequency coil 130 (also referred to as “RF coil”), field generator 140, and spinner drive apparatus 150.

Stator housing 110 is sized and shaped to contain a number of functional elements as described herein, and is further sized and shaped to be couplable to an NMR spectrometer.

In this regard, stator housing 110 includes within it a cavity regions 112, the cavity region being sized and shaped to contain the spinner 120. The radiofrequency coil 130 is similarly sized and shaped to substantially surround the cavity regions 112 (and thus, spinner 120). Radiofrequency coil 130 is thus configured to apply a first magnetic field to the spinner 120 and to the analyte contained therein.

As depicted in FIG. 1B, spinners according to the present disclosure may be cylindrical or substantially cylindrical, such as spinner 120. Spinner 120 is sized and shaped to contain within an analyte, such as in a solution S. When a driving force F from the spinner drive apparatus (such as spinner drive apparatus 150) couples to the coupling apparatus 122, the spinner 120 rotates at a rotational axis within the cavity region 112 of the stator housing 110.

The radiofrequency coil 130 is adjacent to field generator 140. As illustrated, field generator 140 runs parallel to a rotational axis of the spinner 120 and within the coils of radiofrequency coil 130. Without wishing to be bound by any particular theory, when radiofrequency coil 130 applies a first magnetic field, and when field generator 140 applies a second magnetic field, analyte in the spinner 120 experiences a magnetic field that varies in space and time. The rotation of the analyte in the spinner 120 through this gradient causes the nuclear spins to acquire a phase that is proportional to their radial position, which may allow for radially-dependent NMR signal to be acquired.

In this regard, the second magnetic field may represent a pulsed magnetic field gradient. In some embodiments, the second magnetic field may result in a pulsed magnetic field gradient when applied in conjunction with the first magnetic field. The second field direction may be determined based on the needs of a particular experiment. In this regard, there is a distribution of magnetic field values in space inherent to the gradient field generated when the second magnetic field is applied. Such a distribution of magnetic fields, and variations to suit the needs of particular experimentation, are determinable by one of ordinary skill in the art based on the configuration provided to the radiofrequency coil 130 and/or the field generator 140.

It should be noted that, in any of the methods described herein, a third magnetic field may be present that represents a strong magnetic field provided by an NMR spectrometer. In this regard, in any of the embodiments described herein, there may be three magnetic fields: a third magnetic field provided by the NMR spectrometer that is a strong magnetic field, a first magnetic field representing the magnetic field generated by radiofrequency coil 130, and a second magnetic field representing the magnetic field generated by field generator 140, the application of said second magnetic field resulting in a magnetic field gradient experienced by the analyte.

The illustrated embodiment further includes a coupling point 152 (such as an output port when the spinner drive apparatus 150 provide a pneumatic force, or a physical contact point when the spinner drive apparatus 150 provides a mechanical force) coupled to the spinner drive apparatus 150. The illustrated embodiment also includes a vent 154, which may be provided when the coupling point 152 provides a pneumatic force. Coupling point 152 (in the form of an output port) and vent 154 may be included when the spinner drive apparatus 150 provides drive force F via a flow of a gaseous fluid into the cavity region 112, thereby providing a pneumatic driving rotation of the spinner when the gaseous fluid flows over the coupling apparatus 122 and rotates the spinner 120 around a rotational axis. However, it should be understood that other spinner drive apparatus 150 configurations are possible such as where spinner drive apparatus 150 contacts coupling apparatus 122, thereby driving a rotation of spinner 120).

The NMR probe 100 may also be operatively coupled (such as via electronic communication) to a controller C.

In some embodiments, controller C includes at least one processor and a computer-readable medium having computer-executable instructions stored thereon that, in response to execution by the at least one processor, cause the controller C to perform operations including applying a first magnetic field having a first field direction to a spinner, said spinner containing an analyte, and said spinner being disposed in a cavity region of a stator housing; physically rotating the spinner at a spin angle with respect to the first field direction, thereby inducing sedimentation of the analyte; applying a second magnetic field with a second field direction across the analyte; and acquiring a spatially-resolved NMR signal, thereby characterizing the analyte by a radial position of the analyte contained in the spinner.

In some embodiments, the method for performing AUC with NMR detection may be performed with any of the NMR probes described herein.

Thus, it should be understood that NMR probes according to the present disclosure include multiple functional elements, such as one or more tunable radiofrequency (RF) circuits, a temperature control system, and gradient coils (i.e., a field generator) for applying spatially varying magnetic fields. In the case of MAS probes, the NMR probes include a mechanism for pneumatic spinning of the sample.

In some embodiments, the field generator is a gradient wire placed to one side of the spinner, wherein the gradient wire is configured to receive direct current pulses. In some embodiments, the field generator is disposed in an interior region relative to the radiofrequency coils.

In some embodiments, the gradient wire has a diameter from about 0.01 mm to about 2 mm. In some embodiments, the gradient wire has a diameter from about 0.05 mm to about 2 mm, about 0.1 mm to about 2 mm, about 0.5 mm to about 2 mm, or about 1 mm.

In some embodiments, the gradient wire is positioned from about 0.01 mm to about 2 mm away from the spinner. In some embodiments, the gradient wire is positioned about 0.05 mm to about 2 mm away from the spinner, about 0.1 mm to about 2 mm away from the spinner, about 0.5 mm to about 2 mm away from the spinner, or about 1 mm away from the spinner.

In some embodiments, the field gradient generator is a coil surrounding the sample configured to generate a radially symmetric field gradient profile, Gz(r), monotonic with r, with dGz/dr=0 at the center of the sample.

In some embodiments, the radiofrequency coil is configured to provide a radiofrequency pulse of from about 10 MHz to about 1500 MHz.

In any of the embodiments herein, a strength of an alignment magnetic field provided to the NMR probe from an NMR spectrometer is from about 0.1 tesla to about 100 tesla. In an embodiment, the strength of the alignment magnetic field is from about 0.1 tesla to about 75 tesla, about 0.1 tesla to about 50 tesla, from about 0.1 tesla to about 35 tesla, from about 0.1 tesla to about 3 tesla, from about 0.1 tesla to about 2 tesla, from about 0.1 tesla to about 1.5 tesla, from 0.5 tesla to about 1.5 tesla, from 1 tesla to about 1.5 tesla, from about 3 tesla to about 30 tesla, from about 3 tesla to about 28 tesla, from about 7 tesla to about 28 tesla, from about 7 tesla to about 20 tesla, from about 7 tesla to about 15 tesla, from about 15 tesla to about 28 tesla, or from about 20 tesla to about 28 tesla. In some embodiments, the field direction of the alignment magnetic field of the NMR spectrometer is configured to induce an alignment of a plurality of nuclei of the analyte in the analyte solution.

In another aspect, the present disclosure provides a method for performing analytical ultracentrifugation (AUC) with nuclear magnetic resonance (NMR) detection including: applying a first magnetic field having a first field direction to a spinner, said spinner containing an analyte, and said spinner being disposed in a cavity region of a stator housing; physically rotating the spinner at a spin angle with respect to the first field direction, thereby inducing sedimentation of the analyte; applying a second magnetic field with a second field direction across the analyte, thereby generating a magnetic field gradient; and acquiring a spatially-resolved NMR signal, thereby characterizing the analyte by a radial position of the analyte in the spinner.

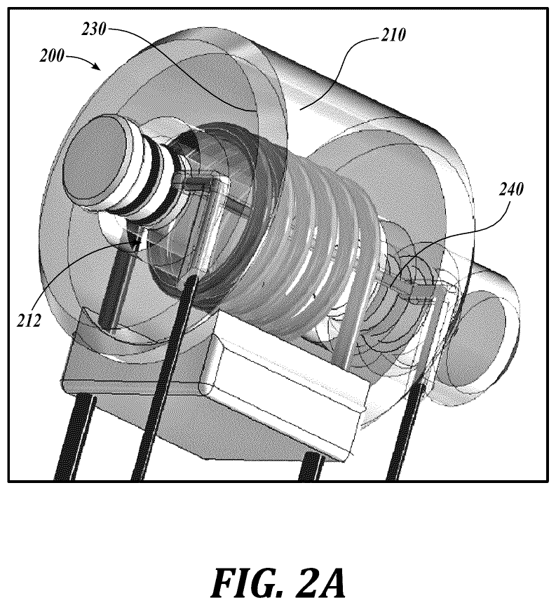

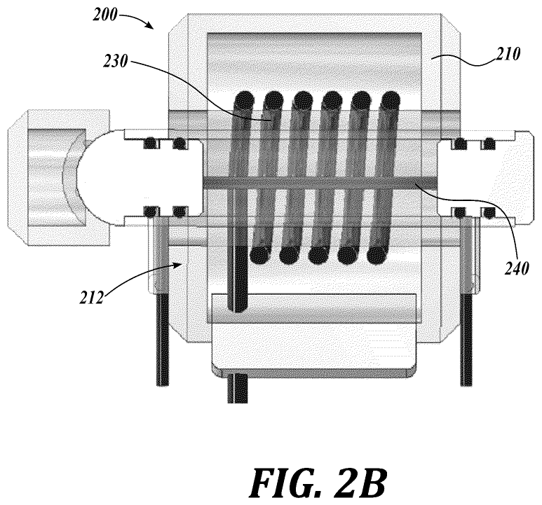

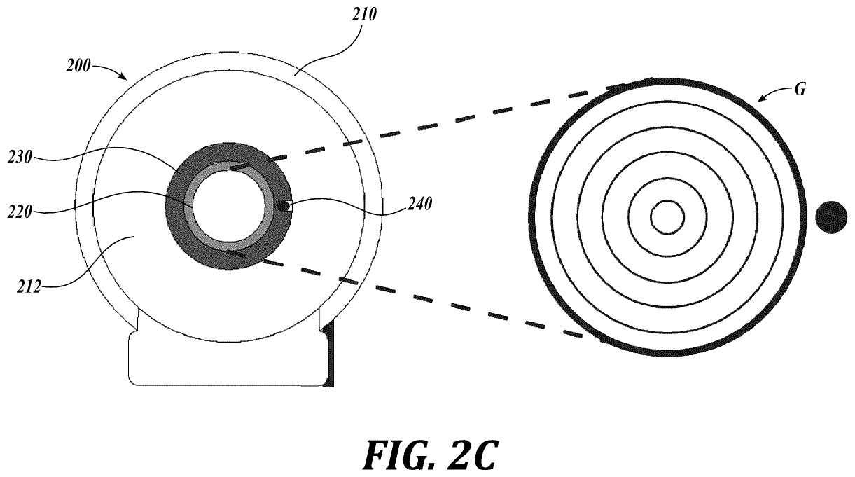

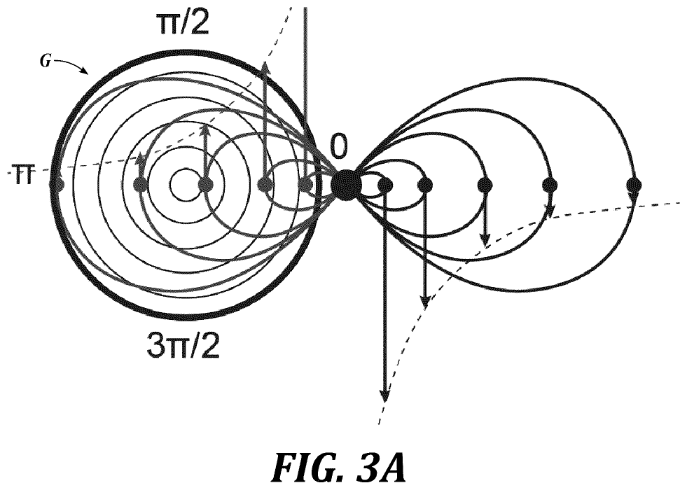

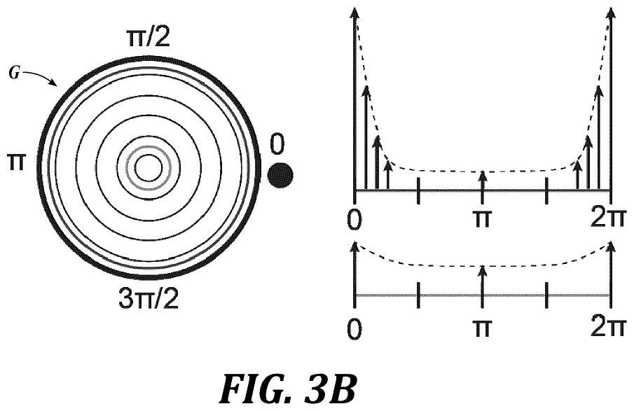

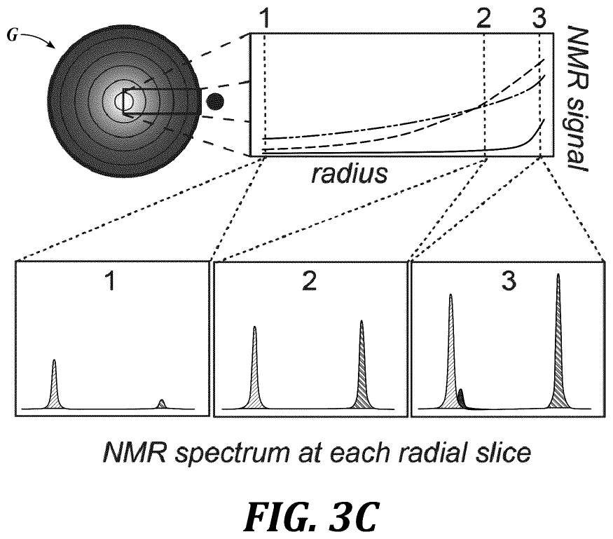

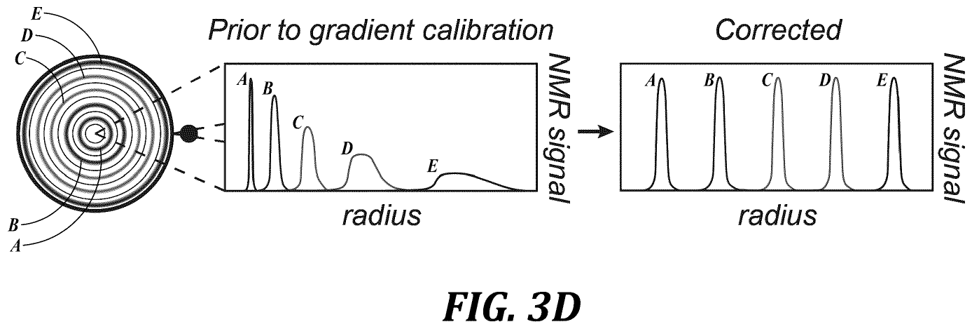

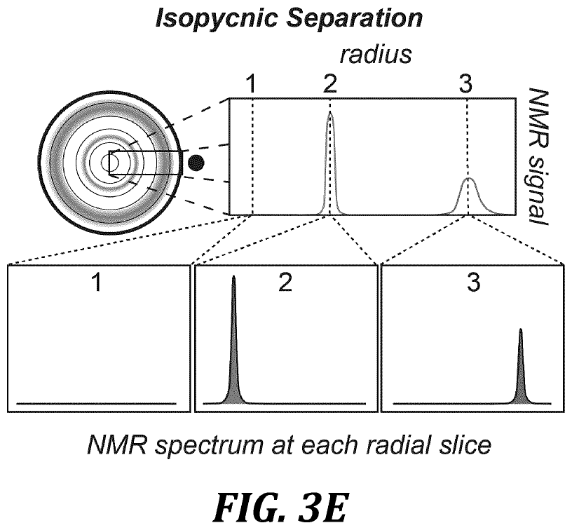

As AUC-NMR is a technique where molecules are probed and discriminated by their radial position, AUC-NMR measures the radial concentration gradient within the spinning sample. In this regard, FIG. 2A and FIG. 2B depict an NMR probe 200 designed to perform this type of radial spatial discrimination, and is thus configured to produce the data depicted in FIG. 3A-3C. While the data depicted in FIG. 3A-3C is derived from an NMR probe with the configuration of NMR probe 200, it should be understood that analogous experiments and others may be performed with any of the NMR probes described herein. In some embodiments, NMR probe 200 is an example of NMR probe 100, and accordingly, for clarity, like elements are described with like numerals except in the 2XX series.

In some embodiments, the NMR probe 200 includes of a cylindrical spinner 220 with a wire (i.e., field generator 240) placed to one side of the sample and within a radiofrequency coil 230, through which direct current (DC) pulses may be applied during the NMR experiment, generating an extremely strong but nonlinear magnetic field distribution across the sample.

Accordingly NMR probe 200 of FIG. 2A-2B includes stator housing 210 with a cavity region 212, a spinner 220, radiofrequency coil 230, and field generator 240.

The setup depicted in FIGS. 2A-2B provides, when in operation, a concentration gradient G within spinner 220 (depicted schematically in FIG. 2C), which may be probed according to the methods described herein, as described further herein.

For instance, FIG. 3A depicts an example of a nonlinear magnetic field distribution produced by the NMR probe 200. Analyte present in a region proximate field generator 240 will experience a relatively stronger magnetic field, whereas analyte present in regions further from the edge of spinner 220 (such as those proximate the center of rotation) will experience a relatively smaller magnetic field.

Thus, though the static field produced by the wire does not directly produce a radial magnetic field gradient, the spinning of the rotor causes the molecules to experience a radially-unique, time-varying magnetic field due to azimuthal variation of the magnetic field.

A schematic of how the magnetic field varies azimuthally is shown in FIG. 3B for a large (top right panel) and small (bottom right panel) radial value. As analyte rotates around the axis of rotation, analyte closer to an external wall of the spinner 220 will experience a greater magnetic field strength when proximate field generator 240, and a weaker magnetic field strength when diametrically opposite to proximate field generator 240. Conversely, analyte closer to the axis of rotation will experience a magnetic field strength that with less dramatic differences between high and low, as the total distance from field generator 240 is smaller.

When the effect of these field profiles is averaged over time under MAS, it results in a nonlinear magnetic field gradient that can distinguish molecules by their radial position.

In some embodiments, this radial magnetic field gradient is modeled and calibrated using a solid phantom sample such as silicone.

In some embodiments, spinner 220 is an example of spinner 120.

In some embodiments, the spinner is a container, such as a sealable tube, configured to receive an analyte solution. In some embodiments, the spinner is a sample rotor, a sample tube, or any other container configured to receive and contain the analyte solution. In some embodiments, the spinner is a solid-state NMR rotor.

In some embodiments, the spinner comprises a tough ceramic, such as sapphire, alumina, silicon nitride, or a zirconia material. In some embodiments, the spinner is a cylindrical spinner. In some embodiments, a diameter of the spinner is from about 0.5 mm to about 20 mm, from about 0.5 mm to about 15 mm, from about 0.5 mm to about 10 mm, from about 0.5 mm to about 9 mm, from about 0.5 mm to about 8 mm, from about 0.5 mm to about 7 mm, from about 0.5 mm to about 6 mm, from about 0.5 mm to about 5 mm, from about 0.5 mm to about 4 mm, from about 0.5 mm to about 3.2 mm, from about 0.5 mm to about 2.5 mm, from about 0.7 mm to about 10 mm, from about 1.3 mm to about 10 mm, from about 2.5 mm to about 10 mm, from about 3.2 to about 10 mm, or from about 5 mm to about 10 mm.

In some embodiments, the analyte is in an analyte solution. However, while for clarity the sample is described as an analyte that is in the form of an analyte solution, any form of sample mixture is within the scope of the present disclosure, such as a suspension, colloidal mixture, gel, or even a solid. In some embodiments, the sample comprises an analyte and a solvent. In some embodiments, the solvent is a deuterated solvent. In some embodiments, the solvent is any acceptable NMR solvent, such as water, hexane, benzene, toluene, DMF, DMSO, THF, acetone, chloroform, dichloromethane, ethanol, methanol, acetonitrile, and trifluoroacetic acid.

In some embodiments, the analyte is selected from the group consisting of proteins, liposomes, nanoparticles, colloids, polymers, biopolymers, small molecules, or combinations thereof.

In some embodiments, the analyte comprises a nucleus that provides an NMR signal. In some embodiments, the nuclei providing the NMR signal is selected from the group consisting of a ¹H NMR nuclei, a ¹³C NMR nuclei, a ³¹P NMR nuclei, and a ¹⁹F NMR nuclei. However, it is to be understood that any nuclei suitable for NMR spectroscopy is within the scope of the present disclosure.

In some embodiments, physically rotating the spinner comprises rotating the spinner along its rotational axis within the stator housing. In some embodiments, the spinner is spun by blowing compressed gas at an impulse air turbine mechanism. In some embodiments, the spinner is suspended in the stator housing within a frictionless compressed gas bearing.

In some embodiments, the spin angle is the magic angle, tan⁻¹(\sqrt{2}) degrees, about 54.74°. In some embodiments, the spin angle is about 0 degrees. In some embodiments, the spin angle is about 90 degrees. In some embodiments, the spin angle is from about 0 degrees to about 10 degrees, from about 10 degrees to about 20 degrees, from about 20 degrees to about 30 degrees, from about 30 degrees to about 40 degrees, from about 40 degrees to about 50 degrees, from about 50 degrees to about 60 degrees, from about 60 degrees to about 70 degrees, from about 70 degrees to about 80 degrees, from about 80 degrees to about 90 degrees, from about 0 degrees to about 90 degrees, from about 10 degrees to about 80 degrees, from about 20 degrees to about 70 degrees, from about 30 degrees to about 60 degrees, from about 0 degrees to about 54.74 degrees, or from about 54.74 degrees to about 90 degrees.

In some embodiments, the rate of rotation of the spinner is sufficient so that the sedimentation of the analyte establishes an analyte concentration gradient with respect to the rotational axis of the spinner. This allows the analyte to separate based on physical properties, such as molecular weight or, when the analyte is one or more chemical compositions contained in an analyte solution, based on intermolecular attractive forces between a first chemical species and other chemical species in the analyte solution, such as with the solvent or with a second chemical species.

In some embodiments, the rate of rotation of the spinner is from about 1 Hz to about 100,000 Hz. In some embodiments, the rate of rotation is from about 1 Hz to about 40,000 Hz, from about 1 Hz to about 25,000 Hz, from about 1 Hz to about 15,000 Hz, from about 1 Hz to about 5,000 Hz, from about 100 Hz to about 25,000 Hz, from about 500 Hz to about 25,000 Hz, from about 1,000 Hz to about 25,000 Hz, from about 2,000 Hz to about 25,000 Hz, from about 3,000 Hz to about 25,000 Hz, from about 4,000 Hz to about 25,000 Hz, from about 5,000 Hz to about 25,000 Hz, from about 1,000 Hz to about 20,000 Hz, from about 1,000 Hz to about 15,000 Hz, from about 1,000 Hz to about 10,000 Hz, from about 1,000 Hz to about 5,000 Hz, from about 10,000 Hz to about 15,000 Hz, or from about 20,000 Hz to about 25,000 Hz.

In some embodiments, the method further includes performing sedimentation velocity analytical ultracentrifugation on the radial concentration distribution. In sedimentation velocity analytical ultracentrifugation, a high-speed centrifuge is used to measure the sedimentation rate of molecules at a number of time points, where the sedimentation rate reflects the size and shape of said molecules. In some embodiments, the method further includes performing sedimentation equilibrium analytical ultracentrifugation on the radial concentration distribution. Without being bound by theory, the rate of rotation is selected for both rapid sedimentation speed while allowing for enough boundary spreading to capture diffusion information.

The magnetic field gradient is the magnetic field applied when a direct current is run through a current carrier (i.e. a field generator and the radiofrequency coil) held adjacent to the spinner. Without being bound by theory, a magnetic field gradient is applied to distinguish nuclear spins based on the radial position of the analyte within the spinner. In some embodiments, the current carrier is a wire. The magnetic field profile is a gradient because the field changes in magnitude as a function of position. In an embodiment, FIG. 3A depicts a magnetic field gradient across an analyte in a spinner in accordance with some embodiments of the present disclosure. In an embodiment, FIG. 3B depicts the variation in magnetic field strength as a function of angle for two radius values. In some embodiments, the magnetic field gradient is linear. In some embodiments, the magnetic field gradient is non-linear. In some embodiments, the magnetic field gradient is radially symmetric about the center of the sample.

In some embodiments, the magnetic field gradient is asymmetric across the sample profile.

In some embodiments, performing magnetic resonance imaging on the analyte solution to generate an NMR signal while spinning allows the NMR signal to be measured as a function of radial position within the spinner. FIG. 3C is an example of a radial concentration profile obtained by NMR detection for two different molecules at two different radial positions within the spinner. Specifically, FIG. 3C depicts a radial concentration profile obtained by NMR detection for three different detected species (dot dashed, solid, and dashed lines), and corresponding NMR spectra (black line on white hatching, solid fill, white line on black hatching) for 3 radial slices for the NMR probe of FIG. 2A. The solid filled feature represents the presence of a dimer species of the molecule represented by the solid line. At radial slice 1, a first species (dot-dashed line, black line on white hatching) is more prevalent than a second species (dashed line, white line on black hatching). At radial slice 2, the first and second species have roughly equivalent prevalences. At radial slice 3, the second species has become more dominant, and a third species representing a dimerized version of the first species (solid line, solid fill) at a position modestly shifted from the first species is detected.

FIG. 3D depicts a gradient correction applied to NMR signal determined at radius positions A-E, demonstrating correction for signal broadening.

FIG. 3E depicts isopycnic separation of signals at three radial slices, depicting (1) a radial slice containing no analyte, (2) a radial slice containing a first analyte with a first NMR signal, and (3) a radial slice containing a second analyte with a second NMR signal.

In some embodiments, the method further comprises processing the NMR signal to generate NMR spectra as a function of radial position. In some embodiments the method further comprises processing the NMR spectrum to generate a radial concentration distribution of the analyte in the analyte solution.

In some embodiments, the method further comprises processing the radial concentration distribution to generate sedimentation coefficients of the analyte in the analyte solution. In some embodiments, the radial magnetic resonance imaging is performed by applying, from a radiofrequency coil and/or gradient coil, a sequence of radiofrequency pulses to the spinner.

In some embodiments, the radial magnetic resonance imaging is based on slice-selective excitation methods. Slice-selective excitation methods allow a user to measure the NMR spectrum at a specific radius in the sample. For example, slice-selective excitation methods comprise radiofrequency pulsing protocols that allow for an NMR signal to be obtained for a particular slice of the analyte contained within the spinner, such as the analyte disposed against the interior spinner wall and the analyte disposed proximate the axis of rotation of the spinner. The spatially-resolved NMR signal may be based on frequency-encoded imaging methods.

In some embodiments, the radial magnetic resonance imaging is based on frequency-encoded imaging methods. Frequency-encoded imaging allows for imaging and chemical shift imaging to be performed of the radial concentration gradient of the analyte.

In some embodiments, the radial magnetic resonance imaging is based on phase-encoded imaging methods. Phase-encoded imaging allows for imaging and chemical shift imaging to be performed of the radial concentration gradient of the analyte.

In some embodiments, the spinner of the NMR probes are as described above for the method. In some embodiments, the sample is an analyte solution as described above for the method. In some embodiments, the analyte is as describe above for the method. In some embodiments, the stator housing of the NMR probes is as described above for the method.

In some embodiments, the radiofrequency coil is configured to substantially surround the spinner. In some embodiments, the field generator is a gradient coil consisting of a single gradient wire placed to one side of the spinner, said wire configured to receive direct current pulses.

In some embodiments, the gradient wire has a diameter from about 0.01 mm to about 2 mm. In some embodiments, the gradient wire has a diameter from about 0.01 mm to about 1.5 mm, from about 0.01 mm to about 1.0 mm, from about 0.1 mm to about 1.0 mm, from about 0.5 mm to about 1.0 mm, or from about 1 mm to about 2 mm.

In some embodiments, the gradient wire is positioned from about 0.01 mm to about 2 mm away from the spinner. In some embodiments, the gradient wire is positioned from about 0.05 mm to about 2 mm away from the spinner, from about 0.05 mm to about 1.5 mm away from the spinner, from about 0.05 mm to about 1.0 mm away from the spinner, from about 0.1 mm to about 1.0 mm away from the spinner, from about 0.2 mm to about 0.9 mm away from the spinner, from about 0.3 mm to about 0.7 mm away from the spinner, or from about 0.4 mm to about 0.6 mm away from the spinner.

In some embodiments, the direct current is pulsed through the gradient wire from about 0.001 A to about 50 A. In some embodiments, the direct current is pulsed from about 0.001 A to about 40 A, from about 0.001 A to about 30 A, from about 0.001 A to about 20 A, from about 0.001 A to about 10 A, from about 0.001 A to about 5 A, from about 0.001 A to about 1 A, from about 0.001 A to about 0.9 A, from about 0.001 A to about 0.8 A, from about 0.001 A to about 0.7 A, from about 0.001 A to about 0.6 A, from about 0.001 A to about 0.5 A, from about 0.01 A to about 1 A, from about 0.1 A to about 1 A, or from about 0.5 A to about 1 A.

In some embodiments, the radiofrequency coil is configured to provide a radiofrequency pulse of from about 10 MHz to about 4280 MHz. In some embodiments, the radiofrequency coil is configured to provide a radiofrequency pulse of from about 10 MHz to about 1500 MHz. In some embodiments, the radiofrequency coil is configured to provide a radiofrequency pulse of from about 300 MHz to about 1200 MHz, from about 300 MHz to about 1000 MHz, from about 300 MHz to about 800 MHz, from about 300 MHz to about 600 MHz, from about 500 MHz to about 1200 MHz, from about 700 MHz to about 1200 MHz, from about 900 MHz to about 1200 MHz, from about 10 MHz to about 50 MHz, from about 10 MHz to about 40 MHz, from about 10 MHz to about 30 MHz, or from about 10 MHz to about 20 MHz.

In some embodiments, the spinner drive and the coupling apparatus are configured to generate a physical rotation of the spinner in the stator housing. Without being bound by theory, the spinner drive is a source of compressed gas that impinges on the spinner, causing it to spin within the stator housing. A second source of compressed gas generates a bearing pressure and maintains physical separation between the rotor and the stator housing during the physical rotation of the spinner.

### Example 1: Sedimentation Equilibrium Experiments

The AUC-NMR probe may be operated to achieve a sedimentation equilibrium distribution for an analyte solution during rotation. In some embodiments, the spinner is rotated at a selected rate until the radial concentration profile reaches a steady state. During rotation, NMR data are acquired and processed to reconstruct a radial concentration distribution (optionally with spectrally resolved information) across the sample cell. The reconstructed steady-state radial concentration distribution may then be analyzed to determine molecular weights and/or intermolecular interaction parameters for the analyte.

The AUC-NMR probe will be operated to achieve an equilibrium concentration distribution of molecules. This equilibrium concentration will be reached within the rotor at a fixed spinning rate, and the radial gradient will be used to perform a magnetic resonance imaging (MRI) technique known as slice-selective excitation, enabling NMR spectra to be measured as a function of radial position and yielding a spectrally resolved radial image of the sample.

The intensity of peaks in each radial slice will correspond to the radial distribution of particles, which will then be used to determine the molecular weight of the molecule.

### Example 2: Sedimentation Experiments for Multi-molecule Samples

An additional advantage of the methods and devices of the present disclosure over traditional AUC with optical detection is that AUC-NMR measures several macromolecules in solution simultaneously. Concentration gradients that would otherwise overlap due to similar optical properties or molecular weights will be discriminated by the spectral resolution afforded by NMR detection.

FIG. 3C depicts an example of concept, whereby the sedimentation of two different molecules will be differentiated by their NMR peaks. The detection of a dimer of one of the species is also demonstrated. Because of the additional axis of discrimination possible because of AUC-NMR, the techniques and devices of the present disclosure provide unprecedented insights into biomolecular systems.

In the detailed description herein, references to “one embodiment”, “an embodiment”, “an example embodiment”, “some embodiments”, “one or more embodiments, etc., indicate that the embodiment described may include a particular feature, structure, or characteristic, but every embodiment may not necessarily include the particular feature, structure, or characteristic. Moreover, such phrases are not necessarily referring to the same embodiment. In addition, when a particular feature, structure, or characteristic is described in connection with an embodiment, it is submitted that it is within the knowledge of one skilled in the art to affect such feature, structure, or characteristic in connection with other embodiments whether or not explicitly described. After reading the description, it will be apparent to one skilled in the relevant art(s) how to implement the disclosure in alternative embodiments. Thus, it will be appreciated that embodiments of the present disclosure may employ any combination of features described herein. All such combinations or sub-combinations of features are within the scope of the present disclosure.

Throughout this specification, terms of art may be used. These terms are to take on their ordinary meaning in the art from which they come, unless specifically defined herein or the context of their use would clearly suggest otherwise.

The drawings in the FIGS. are not to scale. Similar elements are generally denoted by similar references in the FIGS. For the purposes of this disclosure, the same or similar elements may bear the same references. Furthermore, the presence of reference numbers or letters in the drawings cannot be considered limiting, even when such numbers or letters are indicated in the claims.

The present application may include references to “directions,” such as “forward,” “rearward,” “front,” “back,” “ahead,” “behind,” “upward,” “downward,” “above,” “below,” “horizontal,” “vertical,” “top,” “bottom,” “right of the present disclosure, wherein a plurality of grooves extend along the length of the cap drive face. hand,” “left hand,” “in,” “out,” “extended,” “advanced,” “retracted,” “proximal,” and “distal.” These references and other similar references in the present application are only to assist in helping describe and understand the present disclosure (such as when the embodiment is positioned for use) and are not intended to limit the present invention to these directions.

The present application may include modifiers such as the words “generally,” “approximately,” “about,” or “substantially.” These terms are meant to serve as modifiers to indicate that the “dimension,” “shape,” “temperature,” “time,” or other physical parameter in question need not be exact but may vary as long as the function that is required to be performed can be carried out. For example, in the phrase “generally circular in shape,” the shape need not be exactly circular as long as the required function of the structure in question can be carried out. The present application may also reference quantities and numbers. Unless specifically stated, such quantities and numbers are not to be considered restrictive, but exemplary of the possible quantities or numbers associated with the present application. Also in this regard, the present application may use the term “plurality” to reference a quantity or number. In this regard, the term “plurality” is meant to be any number that is more than one, for example, two, three, four, five, etc.

As used herein, the term “about,” “approximately,” etc., means plus or minus 5% of the stated value.

In the claims and for purposes of the present disclosure, the terms “a”, “an”, “the”, and the like, refer to the singular and the plural forms of the object or element referenced.

Embodiments disclosed herein may utilize circuitry in order to implement technologies and methodologies described herein, operatively connect two or more components, generate information, determine operation conditions, control an appliance, device, or method, and/or the like. Circuitry of any type can be used. In an embodiment, circuitry includes, among other things, one or more computing devices such as a processor (e.g., a microprocessor), a central processing unit (CPU), a digital signal processor (DSP), an application-specific integrated circuit (ASIC), a field-programmable gate array (FPGA), or the like, or any combinations thereof, and can include discrete digital or analog circuit elements or electronics, or combinations thereof.

An embodiment includes one or more data stores that, for example, store instructions or data. Non-limiting examples of one or more data stores include volatile memory (e.g., Random Access memory (RAM), Dynamic Random Access memory (DRAM), or the like), non-volatile memory (e.g., Read-Only memory (ROM), Electrically Erasable Programmable Read-Only memory (EEPROM), Compact Disc Read-Only memory (CD-ROM), or the like), persistent memory, or the like. Further non-limiting examples of one or more data stores include Erasable Programmable Read-Only memory (EPROM), flash memory, or the like. The one or more data stores can be connected to, for example, one or more computing devices by one or more instructions, data, or power buses.

In an embodiment, circuitry includes a computer-readable media drive or memory slot configured to accept signal-bearing medium (e.g., computer-readable memory media, computer-readable recording media, or the like). In an embodiment, a program for causing a system to execute any of the disclosed methods can be stored on, for example, a computer-readable recording medium (CRMM), a signal-bearing medium, or the like. Non-limiting examples of signal-bearing media include a recordable type medium such as any form of flash memory, magnetic tape, floppy disk, a hard disk drive, a Compact Disc (CD), a Digital Video Disk (DVD), Blu-Ray Disc, a digital tape, a computer memory, or the like, as well as transmission type medium such as a digital and/or an analog communication medium (e.g., a fiber optic cable, a waveguide, a wired communications link, a wireless communication link (e.g., transmitter, receiver, transceiver, transmission logic, reception logic, etc.). Further non-limiting examples of signal-bearing media include, but are not limited to, DVD-ROM, DVD-RAM, DVD+RW, DVD-RW, DVD-R, DVD+R, CD-ROM, Super Audio CD, CD-R, CD+R, CD+RW, CD-RW, Video Compact Discs, Super Video Discs, flash memory, magnetic tape, magneto-optic disk, MINIDISC, non-volatile memory card, EEPROM, optical disk, optical storage, RAM, ROM, system memory, web server, or the like.

While illustrative embodiments have been illustrated and described, it will be appreciated that various changes can be made therein without departing from the spirit and scope of the invention.

1. A method for performing analytical ultracentrifugation with nuclear magnetic resonance (AUC-NMR) detection, the method comprising:
applying a first magnetic field having a first field direction to a spinner, said spinner containing an analyte, and said spinner being disposed in a cavity region of a stator housing;
physically rotating the spinner at a spin angle with respect to the first field direction, thereby inducing sedimentation of the analyte;
applying a second magnetic field with a second field direction across the analyte, thereby generating a magnetic field gradient; and
acquiring a spatially-resolved NMR signal, thereby characterizing the analyte by a radial position of the analyte in the spinner.

2. The method of claim 1, wherein the spin angle is about 54.74°.

3. The method of claim 1, wherein the magnetic field gradient is linear.

4. The method of claim 1, wherein the magnetic field gradient is non-linear.

5. The method of claim 1, further comprising processing the spatially-resolved NMR signal to generate a radially-resolved NMR spectrum.

6. The method of claim 5, further comprising processing the radially-resolved NMR spectrum to generate a radial concentration distribution of the analyte.

7. The method of claim 6, further comprising processing the radial concentration distribution to generate sedimentation coefficients of the analyte.

8. The method of claim 1, wherein the second magnetic field is generated by pulsing a direct current through a field generator running substantially parallel to the rotational axis of the spinner.

9. The method of claim 1, wherein a rate of rotation of the spinner is sufficient so that the sedimentation of the analyte establishes an analyte concentration gradient with respect to the rotational axis of the spinner.

10. The method of claim 1, wherein the acquiring the spatially-resolved NMR signal is performed by applying, from a radiofrequency coil, a sequence of radiofrequency pulses to the spinner.

11. The method of claim 1, wherein a nucleus providing the NMR signal is selected from the group consisting of a ¹H NMR signal, a ¹³C NMR signal, a ³¹P NMR signal, and a ¹⁹F NMR signal.

12. The method of claim 1, wherein the analyte is selected from the group consisting of proteins, liposomes, nanoparticles, colloids, polymers, biopolymers, and small molecules, and combinations thereof.

13. The method of claim 1, wherein the second magnetic field varies in magnitude and direction over time.

14. An NMR probe for performing analytical ultracentrifugation (AUC) with nuclear magnetic resonance (NMR) detection, the NMR probe comprising:
a stator housing having a cavity region;
a spinner disposed in the cavity region, wherein the spinner is configured to contain an analyte;
a radiofrequency coil disposed in the stator housing and configured to substantially surround the spinner;
a field generator disposed in the stator housing, said field generator being configured to apply a magnetic field to the spinner;
a spinner drive apparatus for providing, at a coupling point thereof, a drive force having an amplitude configured to vary as a function of time with a rotation frequency; and
coupling apparatus for coupling the drive force from the coupling point of said spinner drive apparatus to said spinner, thereby rotating the spinner at the rotation frequency.

15. The NMR probe of claim 14, wherein the field generator is a gradient wire placed to one side of the spinner, wherein the gradient wire is configured to receive direct current pulses.

16. The NMR probe of claim 15, wherein the gradient wire has a diameter from about 0.01 mm to about 2 mm.

17. The NMR probe of claim 15, wherein the gradient wire is positioned from about 0.01 mm to about 2 mm away from the spinner.

18. A method for performing MRI imaging using the NMR probe of claim 15.

19. A method for performing diffusion NMR using the NMR probe of claim 15.

20. A method for performing coherence selection using the NMR probe of claim 15.
